(19) United States
(12) Patent Application Publication
(10) Pub. No.: US 2026/0072071 A1
(43) Pub. Date: Mar. 12, 2026

(54) MULTIFUNCTIONAL ULTRA-HIGH VOLTAGE INSULATION PERFORMANCE TEST PLATFORM DEVICE

(71) Applicant: Hefei Institutes of Physical Sciences, Chinese Academy of Sciences, Hefei (CN)

(72) Inventors: CaiChao JIANG, Hefei (CN); Bo LIU, Hefei (CN); JunJun PAN, Hefei (CN); ShiYong CHEN, Hefei (CN); ZhiMin LIU, Hefei (CN); Sheng LIU, Hefei, Anhui (CN); YuanLai XIE, Hefei (CN)

(21) Appl. No.: 19/294,811

(22) Filed: Aug. 8, 2025

(30) Foreign Application Priority Data
Sep. 12, 2024 (CN) 202411278647.0

(51) Int. Cl. G01R 31/12

(52) U.S. Cl. CPC G01R 31/1272

(57) ABSTRACT

The present invention discloses a multifunctional ultra-high voltage insulation performance test platform device, which is composed of a high voltage wire inlet unit, a vacuum test unit, an auxiliary air extractor group and a maintenance platform. The high voltage wire inlet unit is composed of a high voltage power supply, a power supply tank body, a pressure gauge, a shielding ring, a conductor support frame, a corrugated pipe, a vacuum epoxy fiberglass cylinder, a conductive plate, a high voltage conductor, an inner shielding cover, a pressure relief device, SF6 gas, etc. The vacuum test unit is composed of a vacuum tank body, a pressure-resistant contact, an insulation platform, a KF25 connector, a CF35 interface, a vacuum pump interface, an access door, an observation window and a secondary wiring board, etc. And the auxiliary air extractor group can ensure the vacuum degree of the vacuum chamber. The maintenance platform adopts an aluminum alloy profile structure to ensure the strength and at the same time ensure the overall aesthetic appearance.

### BACKGROUND

### Technical Field

The present invention is dedicated to the technical field of high voltage direct current insulation, and particularly focuses on a multifunctional ultra-high voltage insulation performance test platform device. The device is designed to solve the key problems in the evaluation of high voltage direct current insulation performance, such as diversified test requirements, high safety requirements and the balance of test efficiency and accuracy, and to provide an efficient, accurate and adaptable test solution for power transmission, accelerator technology, semiconductor manufacturing and other industries that need high voltage insulation protection.

### Description of the Related Art

In recent years, in view of the rising voltage demand of high voltage transmission system for power transmission, the structure of power supply busbar has gradually turned to adopting metal-enclosed gas insulation technology (GIS), which significantly reduces the floor space, exhibits excellent anti-interference ability of external electromagnetic environment and is convenient for operation and management. Currently, sulfur hexafluoride (SF6) and dry air are widely used as the key insulating medium of choice because of their excellent insulation characteristics, and the research on the insulation performance of internal insulating components has stepped into the mature stage.

However, in certain application scenarios, such as where extremely high purity is required or where release of certain chemicals is to be avoided, vacuum insulation technology becomes a necessary option. Although the performance evaluation of insulation components in vacuum media has accumulated some literature and practical experience in low voltage environment, the relevant performance data is still scarce in high voltage environment, and there is no direct reference standard. Therefore, in the design of high voltage vacuum insulation, estimation and simulation methods are often relied on, which leads to two major challenges in the design process: on the one hand, insufficient design margin may cause discharge breakdown in the process of power-on, which seriously threatens the safety of the system; on the other hand, excessively increasing the design margin for safety can lead to a significant increase in equipment volume and unnecessary waste of raw material resources. Therefore, it is an urgent technical problem to explore the precise design theory and method applicable to high voltage vacuum insulation.

### BRIEF SUMMARY

It is a core object of the present invention to design and implement a high performance ultra-high voltage insulation performance test platform device that integrates multifunctionality in order to overcome the limitations of the prior art. The device is designed to comprehensively evaluate the voltage resistant characteristics of various materials in the vacuum environment for ultra-high voltage insulation, accurately measure and record the key parameters, and on this basis, scientifically establish the vacuum insulation parameter standards for high voltage components to ensure that the insulation performance is fully met, and effectively optimize the overall size of the equipment to achieve the miniaturization of the volume.

In addition, the test platform device also has flexible gas injection function, which can accommodate and test the insulation performance of various gases under various conditions, including but not limited to the effects of temperature, pressure and other variables on the insulation performance, so as to provide solid data support and technical guidance for the selection and optimization of gas insulation materials in different application scenarios.

In order to achieve the above-mentioned object, a multifunctional ultra-high voltage insulation performance test platform device of the present invention is composed of a high voltage wire inlet unit, a vacuum test unit, an auxiliary air extractor group and a maintenance platform; wherein,
the high voltage wire inlet unit is provided for placing a high voltage power supply, and the interior is filled with SF6 gas;
the vacuum test unit is provided for testing the insulation characteristic of the insulation piece, and the interior is evacuated;
the auxiliary air extractor group is provided for air extraction of the vacuum test unit to ensure an internal vacuum degree;
the maintenance platform is provided for the convenience of personnel operation during maintenance;
the high voltage wire inlet units are respectively mounted on two sides of the vacuum test unit; the auxiliary air extractor group is connected to the vacuum test unit, and the maintenance platform is placed at a maintenance opening of the vacuum test unit.

The significant technical advantages and beneficial effects exhibited by the present invention are as follows:

1. Extensive suitability testing capability: the present invention provides a multifunctional test platform capable of flexibly responding to the test requirements of insulation pieces with different sizes under a wide range of conditions, including but not limited to the ultra-high voltage direct current voltage resistant test under different vacuum degree environments and filled with different pressure and different types of gases. The high degree of configurability ensures the comprehensiveness and accuracy of the insulation performance evaluation, and meets the test requirements in a variety of application scenarios.

2. Insulation performance test of large area high-energy positive and negative ion sources: furthermore, the platform can test the insulation performance of large area, high-energy positive and negative ion source accelerating electrodes under different vacuum conditions, which fills the gap of traditional test methods in the insulation evaluation of such complex and high-performance electrodes, and provides strong support for the insulation design of advanced accelerator system, ion beam technology and other fields.

3. Space optimization and floor space reduction: through careful structural design and layout optimization, the test platform of the present invention achieves a significant reduction in the overall volume, effectively reduces the floor space, improves the space efficiency of the test laboratory, and is also conducive to the transport and deployment of test equipment.

4. Intensification of operational safety: considering the electrical safety during the test, the present invention designs all the tank housings to the ground potential, which fundamentally eliminates the risk of electric shock to the operator, ensures the safety of the test process, reduces the possibility of accidents, and improves the reliability and maintainability of the whole test system.

### BRIEF DESCRIPTION OF THE SEVERAL VIEWS OF THE DRAWINGS

In order to explain the technical solution of the present invention more clearly, the drawings used in the description will be briefly introduced as follows. It is obvious that the drawings in the following description are only some embodiments of the present invention, and it would have been obvious for a person of ordinary skill in the art to obtain other drawings according to these drawings without involving any inventive effort.

FIG. 1 is a schematic front view of the present invention;

FIG. 2 is a schematic side view of the present invention;

FIG. 3 is a cross-sectional view of the interior of the present invention;

FIG. 4 is a connection diagram of vacuum epoxy fiberglass cylinder.

In the figures: 1—high voltage wire inlet unit, 2—vacuum test unit, 3—auxiliary air extractor group, 4—maintenance platform, 5—high voltage power supply, 6—power supply tank body, 7—pressure gauge, 8—shielding ring, 9—conductor support frame, 10—corrugated pipe, 11—vacuum epoxy fiberglass cylinder, 12—conductive plate, 13—high voltage conductor, 14—inner shielding cover, 15—pressure relief device, 16—SF6 gas, 17—vacuum tank body, 18—pressure-resistant contact, 19—insulation platform, 20—KF25 connector, 21—CF35 interface, 22—vacuum pump interface, 23—access door, 24—observation window, 25—secondary wiring board.

### DETAILED DESCRIPTION

The objects, features and advantages of the present invention will be more apparent and understood from the following description. Below, specific embodiments and accompanying drawings will be used to provide a clear and complete description of the technical solution protected by the present invention. Obviously, the newly described embodiments are only a part of the embodiments of the present invention, and all embodiments are based on the embodiments of the present invention. All other embodiments obtained by ordinary technical personnel in this field without inventive effort are based on the embodiments of the present invention. All fall within the scope of protection of the present invention.

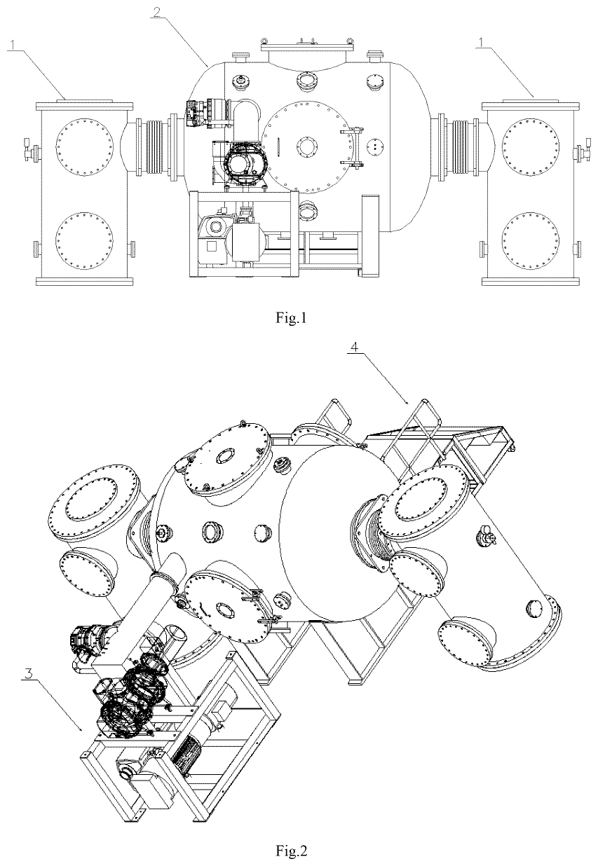

The present invention provides a multifunctional ultra-high voltage insulation performance test platform device, and with reference to FIGS. 1 and 2, the device is composed of a high voltage wire inlet unit 1, a vacuum test unit 2, an auxiliary air extractor group 3 and a maintenance platform 4. Wherein the high voltage wire inlet unit 1 is provided for placing a high voltage power supply 5, and the interior is filled with SF6 gas 16; the vacuum test unit 2 is provided for testing the insulation characteristic of the insulation piece, and the interior is evacuated; the auxiliary air extractor group 3 is provided for air extraction of the vacuum test unit 1 to ensure the internal vacuum degree; the maintenance platform 4 is provided for the convenience of personnel operation during maintenance; two sets of high voltage wire inlet units 1 are respectively mounted on two sides of the vacuum test unit 2, and are butt-jointed with flanges. The auxiliary air extractor group 3 is connected to the vacuum test unit 2 via a stainless steel pipeline, and a maintenance platform 4 is placed at a maintenance opening of the vacuum test unit 2.

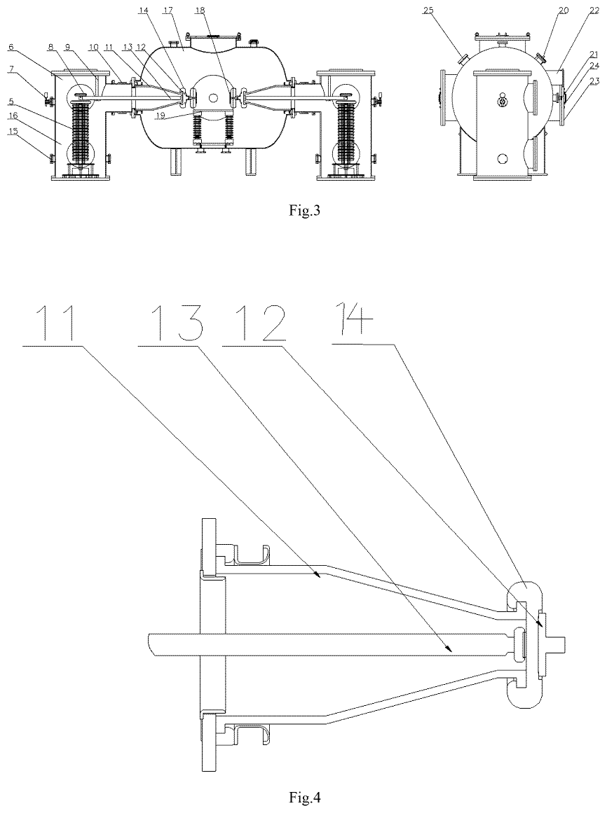

As shown in FIGS. 3 and 4, the high voltage wire inlet unit 1 is composed of a high voltage power supply 5, a power supply tank body 6, a pressure gauge 7, a shielding ring 8, a conductor support frame 9, a corrugated pipe 10, a vacuum epoxy fiberglass cylinder 11, a conductive plate 12, a high voltage conductor 13, an inner shielding cover 14, a pressure relief device 15 and SF6 gas 16. The interior of the high voltage wire inlet unit 1 is filled with SF6 gas 16; the high voltage power supply 5 is fixed on the power supply tank body 6; the high voltage wire outlet of the high voltage power supply 5 is connected to the vacuum test unit 2 via a high voltage conductor 13, and is led out by a conductive plate 12; two ends of the high voltage conductor 13 are respectively supported by a conductor support frame 9 and a vacuum epoxy fiberglass cylinder 11; and a pressure relief device 15 is mounted on a beveled flange on the power supply tank body 6. The pressure gauge 7 monitors the gas pressure of the power supply tank body 6 in real time. The pressure relief device 15 is provided for relieving pressure to ensure the safety of the person.

In the present invention, the shielding ring 8 is mounted on the top of the high voltage power supply 5 and is provided for fixing the other end of the high voltage conductor 13, and serves as a shielding sharp corner.

In the present invention, the corrugated pipe 10, which is mounted between the high voltage wire inlet unit 1 and the vacuum test unit 2, is provided for absorbing mounting errors and ensuring an integral seal;

In the present invention, the inner shielding cover 14 is fixed at the position of a small flange of the vacuum epoxy fiberglass cylinder 11 for improving the electric field distribution of the high voltage conductor.

In the present invention, the vacuum test unit 2 is composed of a vacuum tank body 17, a pressure-resistant contact 18, an insulation platform 19, a KF25 connector 20, a CF35 interface 21, a vacuum pump interface 22, an access door 23, an observation window 24, and a secondary wiring board 25. The KF25 connector 20, the CF35 interface 21, the vacuum pump interface 22, the access door 23, the observation window 24, and the secondary wiring board 25 are respectively fixed to the vacuum tank body 17, the insulation platform 19 is fixed to the bottom of the vacuum tank body 17, and the pressure-resistant contact 18 is fixed to the conductive plate 12.

In the present invention, the KF25 connector 20 and the CF35 interface 21 are vacuum output interfaces which are mainly provided for connecting to a molecular pump.

In the present invention, the vacuum pump interface 22 is mainly used to connect a molecular pump assembly.

In the present invention, the access door 23 is mainly provided for the entrance and exit of experimental equipment and the entrance and exit of personnel, so as to facilitate the entrance and exit of equipment and personnel maintenance.

In the present invention, the auxiliary air extractor group 3 can ensure the vacuum degree of the vacuum chamber.

In the present invention, the maintenance platform 4 adopts an aluminum alloy profile structure to ensure the strength and at the same time ensure the overall aesthetic appearance.

In the present invention, the high voltage power supply 5 is designed with an annular shielding structure by using a resistive voltage divider to ensure uniform electric field.

In the present invention, the power supply tank body 6 is manufactured by welding a steel plate (or an aluminum alloy plate) to secure a sufficient tensile strength.

In the present invention, the pressure gauge 7 is designed with a remote transmission function, which can monitor the gas pressure of the power supply tank body in real time and ensure the internal insulation performance.

And as shown in FIG. 4, the vacuum epoxy fiberglass cylinder 11 adopts a high-strength glass filament winding process to ensure the overall strength, and relies on epoxy resin insulation to ensure the insulation performance. The overall structure is designed to be tapered with one end connected to the high potential and one end connected to the ground potential. One end of the vacuum epoxy fiberglass cylinder 11 is fixed on the vacuum tank body 17, and the other end is connected to the conductive plate 12, and the high voltage conductor 13 passes through the vacuum epoxy fiberglass cylinder 11 and is fixed on the conductive plate 12.

In the present invention, the pressure relief device 15 is made of stainless steel, and is integrally designed with an upper limit of pressure so as to ensure personal safety.

In the present invention, the SF6 gas 16 has a high insulation performance and is a good insulating medium.

In the present invention, the vacuum tank body 17 is made of a steel plate material to ensure a mechanical strength under a negative pressure.

In the present invention, the pressure-resistant contact 18 is designed as an adjustable structure, and the corresponding insulation pressure-resistant distance requirements are adjusted according to different voltage levels.

In the present invention, the insulating platform 19 is composed of a polytetrafluoroethylene material to ensure the insulation performance under vacuum.

In the present invention, the secondary wiring board 25 is provided with a ceramic insulation seal, and is integrally designed in aviation plug form, and is provided for live measurement in a vacuum chamber.

In the present invention, the observation window 24 is made of a tempered glass material so as to ensure mechanical strength while better observing whether there is corona and ignition discharge inside.

The specific operation process of the present invention is as follows: a test piece is fixed on an insulating platform 19, two ends of the test piece are respectively connected to pressure-resistant contacts 18 at two sides, an access door 23 is closed, an auxiliary air extractor group 3 is evacuated to a test vacuum degree, a high voltage power supply 5 in a high voltage wire inlet unit 1 at two sides is provided with positive and negative high voltage voltages, the voltages are started, and a pressure-resistant test is performed.

Various embodiments are described in the specification in a progressive manner, with each embodiment focusing on differences from the other embodiments, with like parts referring to each other.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the present invention. Thus, the present invention is not intended to be limited to the embodiments shown herein but is to be accorded the widest scope consistent with the principles and novel and inventive features disclosed herein.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A multifunctional ultra-high voltage insulation performance test platform device, characterized in that the device is composed of a high voltage wire inlet unit, a vacuum test unit, an auxiliary air extractor group and a maintenance platform; wherein,
the high voltage wire inlet unit is provided for placing a high voltage power supply, and the interior is filled with SF6 gas;
the vacuum test unit is provided for testing the insulation characteristic of the insulation piece, and the interior is evacuated;
the auxiliary air extractor group is provided for air extraction of the vacuum test unit to ensure an internal vacuum degree;
the maintenance platform is provided for the convenience of personnel operation during maintenance;
the high voltage wire inlet units are respectively mounted on two sides of the vacuum test unit; the auxiliary air extractor group is connected to the vacuum test unit, and the maintenance platform is placed at a maintenance opening of the vacuum test unit;
the high voltage wire inlet unit comprises a high voltage power supply, a power supply tank body, a shielding ring, a conductor support frame, a corrugated pipe, a vacuum epoxy fiberglass cylinder, a conductive plate, a high voltage conductor, an inner shielding cover, a pressure relief device and SF6 gas; the interior of the high voltage wire inlet unit is filled with SF6 gas, the high voltage power supply is fixed on the power supply tank body, a high voltage wire outlet of the high voltage power supply is connected to the vacuum test unit via a high voltage conductor and is led out by a conductive plate, two ends of the high voltage conductor are respectively supported by a conductor support frame and the vacuum epoxy fiberglass cylinder, and the pressure relief device is mounted on a beveled flange on the power supply tank body; the shielding ring is mounted on a top of the high voltage power supply and is provided for fixing the other end of the high voltage conductor; the corrugated pipe is mounted between the high voltage wire inlet unit and the vacuum test unit; the inner shielding cover is fixed at the position of a small flange of the vacuum epoxy fiberglass cylinder;
the high voltage power supply adopts a stepped voltage-multiplying circuit structure design, and is provided with an annular shielding structure.

2. The multifunctional ultra-high voltage insulation performance test platform device according to claim 1, characterized in that the vacuum test unit comprises a vacuum tank body, a pressure-resistant contact, an insulation platform, a KF25 connector, a CF35 interface, a vacuum pump interface, an access door, an observation window and a secondary wiring board; wherein the KF25 connector, the CF35 interface, the vacuum pump interface, the access door, the observation window and the secondary wiring board are respectively fixed to the vacuum tank body, the insulation platform is fixed to the bottom of the vacuum tank body, and the pressure-resistant contact is fixed to the conductive plate; the KF25 connector and the CF35 interface are vacuum output interfaces for connecting to a molecular pump; the vacuum pump interface is provided for connecting to a molecular pump assembly; the access door is provided for the entrance and exit of experimental equipment and personnel.

3. The multifunctional ultra-high voltage insulation performance test platform device according to claim 1, characterized in that the auxiliary air extractor group is provided for evacuating a vacuum tank body and is composed of a mechanical pump, a Roots pump and a molecular pump.

4. The multifunctional ultra-high voltage insulation performance test platform device according to claim 1, characterized in that the maintenance platform adopts an aluminum alloy profile structure.

5. The multifunctional ultra-high voltage insulation performance test platform device according to claim 1, characterized in that the power supply tank body is made of welded steel plate or aluminum alloy plate.

6. The multifunctional ultra-high voltage insulation performance test platform device according to claim 1, characterized in that the high voltage wire inlet unit further comprises a pressure gauge for monitoring a gas pressure of the power supply tank body in real time.

7. The multifunctional ultra-high voltage insulation performance test platform device according to claim 1, characterized in that the vacuum epoxy fiberglass cylinder is insulated by epoxy resin and is manufactured by glass filament winding process.

8. The multifunctional ultra-high voltage insulation performance test platform device according to claim 1, characterized in that the pressure relief device is made of stainless steel.

9. The multifunctional ultra-high voltage insulation performance test platform device according to claim 2, characterized in that the vacuum tank body is made of steel plate material.

10. The multifunctional ultra-high voltage insulation performance test platform device according to claim 2, characterized in that the pressure-resistant contact is of an adjustable structure, and the corresponding insulation pressure-resistant distance requirements are adjusted according to different voltage levels.

11. The multifunctional ultra-high voltage insulation performance test platform device according to claim 2, characterized in that the insulation platform is made of polytetrafluoroethylene material.

12. The multifunctional ultra-high voltage insulation performance test platform device according to claim 2, characterized in that the secondary wiring board adopts ceramic insulation sealing and aviation plug form, and is provided for live measurement in a vacuum chamber.

13. The multifunctional ultra-high voltage insulation performance test platform device according to claim 2, characterized in that the observation window is made of tempered glass material.
